(19) United States
(12) Patent Application Publication
(10) Pub. No.: US 2024/0153552 A1
(43) Pub. Date: May 9, 2024

(54) MEMORY ARRAY FOR COMPUTE-IN-MEMORY AND THE OPERATING METHOD THEREOF

(71) Applicant: NATIONAL YANG MING CHIAO TUNG UNIVERSITY, Hsinchu (TW)

(72) Inventors: Tian-Sheuan Chang, Hsinchu (TW); Wei-Zen Chen, Hsinchu (TW); Shyh-Jye Jou, Hsinchu (TW); Shu-Hung Kuo, Hsinchu (TW); Shih-Hang Kao, Hsinchu (TW); Li-Kai Chen, Hsinchu (TW)

(73) Assignee: NATIONAL YANG MING CHIAO TUNG UNIVERSITY, Hsinchu (TW)

(21) Appl. No.: 18/175,895

(22) Filed: Feb. 28, 2023

(30) Foreign Application Priority Data
Nov. 7, 2022 (TW) 111142460

(51) Int. Cl. G11C 11/54; G11C 11/408; G11C 11/4097

(52) U.S. Cl. CPC G11C 11/54; G11C 11/4085; G11C 11/4097

(57) ABSTRACT

A memory array for computing-in-memory (CIM) is disclosed. The memory array for CIM includes a bit cell array, at least one word line and at least one bit line. The bit cell array has a plurality of bit cells, wherein each bit cell is operated at an operating voltage. The at least one word line is electrically connected to the bit cell array, wherein the at least one word line is associated with a first parameter. The at least one bit line is electrically connected to the bit cell array, wherein the bit cells extend along a specific direction, each the at least one bit line has an electrical parameter associated therewith, each the bit cell is associated with a second parameter, a first quantity of the plurality of bit cells of the bit cell array extends along the specific direction, and the memory array determines how an expansion associated with at least one of the first parameter and the second parameter is according to the specific direction.

### CROSS-REFERENCE TO RELATED APPLICATION AND CLAIM OF PRIORITY

The application claims the benefit of Taiwan Application No. 111142460, filed on Nov. 7, 2022, at the TIPO, the disclosures of which are incorporated herein in their entirety by reference.

### FIELD OF THE INVENTION

The present disclosure relates to memory arrays and the operating methods thereof, and particularly to memory arrays and the operating methods thereof for use in artificial intelligence.

### BACKGROUND OF THE INVENTION

Deep learning is an important part of Artificial Intelligence (AI) chips, and smart consumer electronic products occupy a pivotal position in both the US and global electronic markets. According to the report of the market research organization IDC, it is estimated that the AI industry will grow at an integral annual growth rate of 17.5% in the future, and the total revenue will exceed US$500 billion by 2024. According to the contents of CES 2022, the exhibition shows that computers, electric vehicles, health care and metaverse applications are the main topic of this exhibition, all of which are extended applications centered on AI smart chips, which shows that the AI technology plays an important role on the development of the industry.

At the Consumer Electronics Show (CES) 2022 in the United States, it can be observed that as the high-speed and low-latency 5G network has gradually matured, coupled with the rise of the Internet of terminal electronic devices, traditional devices are transforming into connected devices. The foundation of the advanced semiconductor technology will further accelerate the rise of various fields such as the smart home, smart wear, smart manufacturing, smart city and self-driving car. Most of these are extended applications with AI smart chips as the main feature, which shows the development and influence of AI technology on the industry. Therefore, the development of low-energy AI chip systems is an inevitable development trend.

Deep learning adopts neural network computations, which will use a large number of multiplication and addition operations. When these operations are executed on traditional Von Neumann architecture that has separated computation and memory storage, it will face the power consumption generated by a large amount of data transfer. In contrast, Compute-in-Memory (CIM) integrates computation and memory storage, which can save a lot of the data access, and has a high potential to achieve low energy consumption and high energy efficiency for the neural network execution.

The accuracy of the neural network is very sensitive to the data bit width, but the floating-point calculation is very heavy on the hardware operation. Therefore, in order to achieve low energy consumption and high calculation load, it is highly potential to run multiple bit multiplication on the CIM architecture.

In prior arts, when CIM performs multi-bit multiplication and addition, (for example, multiply input IN[1:0] with weight W, IN[1:0]*W (weight)), IN[1:0] will be converted to analog voltage as the voltage of the read word line (RWL) to control the original current flow through the RWL on the SRAM cell to be 1 times, ⅔ times or ⅓ times the original current, and t, so that the voltage drop caused by each SRAM cell on the read bit line (RBL) becomes 1 times, ⅔ times or ⅓ times the original voltage drop, thereby realizing the multi-bit multiplication and addition operations. Another method in the prior art is to maintain the RWL at the same operating voltage. By changing the RWL pulse width or increasing the number of RWL pulses, the voltage drop caused by each SRAM cell on the RBL becomes 3 times, 2 times or 1 times the original voltage drop, thereby realizing the multi-bit multiplication and addition operations.

In Document 1 of the U.S. Pat. No. 11,061,646, there are two techniques used. One is to change the pre-charge voltages of the RBL, and thereby generate an SRAM array of multiple voltages to change the current generated by the SRAM cell of each sub-array to represent the weight. It eliminates the need to adjust the RWL voltage level and simplifies the circuit design. The other is to change the pulse width of the RWL, so that the voltage drop generated by the SRAM cell after starting the RWL can be controlled by RWL pulse width to generate weights.

In Document 2 of M. Ali, A. Jaiswal, S. Kodge, A. Agrawal, I. Chakraborty and K. Roy et al., proposed “IMAC: In-Memory Multi-Bit Multiplication and Accumulation in 6T SRAM Array,” in IEEE Transactions on Circuits and Systems I: Regular Papers, vol. 67, no. 8, pp. 2521-2531, Aug. 2020, the method used is to change the pulse width of RWL to control the voltage drop on RBL, to realize the weight of the data.

In Document 3 of M. E. Sinangil et al., proposed “A 7-nm Compute-in-Memory SRAM Macro Supporting Multi-Bit Input, Weight and Output and Achieving 351 TOPS/W and 372.4 GOPS,” in IEEE Journal of Solid- State Circuits, vol. 56, no. 1, pp. 188-198, Jan. 2021, the method used is to increase the number of RWL pulses to control the voltage drop on the RBL to achieve the weight of the data.

In Document 4 of X. Si et al., it proposed “A Local Computing Cell and 6T SRAM-Based Computing-in-Memory Macro With 8-b MAC Operation for Edge AI Chips,” in IEEE Journal of Solid-State Circuits, vol. 56, no. 9, pp. 2817-2831, Sept. 2021. In Document 5 of X. Si et al., it proposed “15.5 A 28 nm 64 Kb 6T SRAM Computing-in-Memory Macro with 8b MAC Operation for AI Edge Chips,” 2020 IEEE International Solid-State Circuits Conference—(ISSCC), 2020, pp. 246-248. In Document 6 of X. Si et al., it proposed “24.5 A Twin-8T SRAM Computation-In-Memory Macro for Multiple-Bit CNN-Based Machine Learning,” 2019 IEEE International Solid-State Circuits Conference—(ISSCC), 2019, pp. 396-398. All the Documents 4, 5, and 6 adjust the voltage level of the RWL pulse to change the current generated by the SRAM cell to control the voltage drop of the RBL to achieve data weighting. Document 6 also changes the transistor width of the SRAM cell to increase the current generated by the SRAM cell to control the voltage drop of the RBL and realize data weighting.

The above methods are mainly for processing the analog signal of the RWL pulse. Since the RWL signal is a relatively high-frequency signal, the analog circuit for dynamic processing will have problems of high hardware complexity and high power consumption. In addition, these memory arrays and their operating methods in the conventional technology are all for processing the higher frequency RWL signal, which is difficult to be realized on an analog circuit. Moreover, the resulting energy consumption and area cost are higher, and the operation can only be completed after the analog signal is stable. Therefore, the operating frequency during the CIM macro operation will be limited, and the operation delay will also be limited.

### SUMMARY OF THE INVENTION

In view of the deficiencies of the prior art, the present disclosure takes the area advantage of the large-scale CIM, and expands the weight of the input feature data in the form of the quantity of bit cells, or uses different operating voltage for the bit cells to generate a weighted current, and the multi-bit multiplication and addition can be achieved by starting the RWL once. Compared with the conventional technology for processing the RWL signal, the computation time can be greatly reduced.

In accordance with one aspect of the present invention, a memory array used for computing-in-memory (CIM) is disclosed. The memory array used for CIM includes a bit cell array, at least one word line, at least one bit line and a reading circuit. The bit cell array includes a plurality of bit cells, wherein each of the plurality of bit cells has a storage bit and operates at an operating voltage, and the plurality of storage bits are associated with a weight bit of a convolutional neural network (CNN). The at least one word line is electrically connected to the bit cell array, wherein the at least one of word line is associated with an input bit of the CNN. The at least one bit line is electrically connected to the bit cell array, wherein the plurality of bit cells are arranged along at least one of a bit line direction and a word line direction, each the at least one bit line has an electrical parameter, a first plurality of bit cells of the bit cell array are arranged along the bit line direction according to a first arrangement quantity, the memory array expands the input bit of the CNN to a plurality of input bits based on at least one of the first arrangement quantity and the operating voltage, and at least one of the first arrangement quantity and the operating voltage is a first weight associated with the first plurality of input bits. The reading circuit is electrically connected to and sensing the electrical parameter of each the at least one bit line to obtain a multiplication and addition result of the plurality of input bits of the CNN and the corresponding weight bits thereof.

In accordance with another aspect of the present invention, a method for operating a memory array is disclosed. The memory array includes a bit cell array including a plurality of bit cells, each of which has a storage bit and an operating voltage, the plurality of storage bits are associated with a weight bit of a convolutional neural network (CNN), and the method includes the following steps: providing at least one word line and at least one bit line electrically connected to the bit cell array, wherein the at least one word line is associated with an input bit of the CNN, the plurality of bit cells are arranged along at least one of a bit line direction and a word line direction, each the at least one bit line has an electrical parameter, and a first plurality of bit cells of the bit cell array are arranged along the bit line direction according to a first arrangement quantity; expanding the input bit of the CNN into a plurality of input bits based on at least one of the first arrangement quantity and the operating voltage; correlating at least one of the first arrangement quantity and the operating voltage with a first weight of the plurality of input bits; and sensing the electrical parameter of the at least one bit line to obtain a multiplication and addition result of the plurality of input bits of the CNN and the corresponding weight bits thereof.

In accordance with a further aspect of the present invention, a memory array for computing-in-memory (CIM) is disclosed. The memory array for computing-in-memory (CIM) includes a bit cell array, at least one word line and at least one bit line. The bit cell array has a plurality of bit cells, wherein each bit cell is operated at an operating voltage. The at least one word line is electrically connected to the bit cell array, wherein the at least one word line is associated with a first parameter. The at least one bit line is electrically connected to the bit cell array, wherein the bit cells extend along a specific direction, each the at least one bit line has an electrical parameter associated therewith, each the bit cell is associated with a second parameter, a first quantity of the plurality of bit cells of the bit cell array extends along the specific direction, and the memory array determines how an expansion associated with at least one of the first parameter and the second parameter is according to the specific direction.

The above objectives and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a schematic diagram showing multi-bit multiplication and addition operated by a CNN in a preferred embodiment of the present disclosure;

FIG. 2 is a schematic diagram of a CIM according to a preferred embodiment of the present disclosure;

FIG. 3 is a schematic diagram of a memory array for CIM in a preferred embodiment of the present disclosure;

FIG. 4 is a schematic diagram of implementing multi-bit multiplication and addition of a memory array used in a CIM according to a preferred embodiment of the present disclosure;

FIG. 5 is a schematic diagram of using the voltage regulating circuit to provide different operating voltages to multiple bit cells according to a preferred embodiment of the present disclosure;

FIG. 6 is a schematic diagram of providing different operating voltages to bit cells to implement multiplication and addition of multi-input bits for a memory array used in CIM according to a preferred embodiment of the present disclosure;

FIG. 7 is a schematic diagram of providing different operating voltages to bit cells to implement multiplication and addition of multi-input bits for a memory array used in CIM according to another preferred embodiment of the present disclosure;

FIG. 8 is a schematic diagram of providing different operating voltages to the bit cells to implement multi-weight bit multiplication and addition for the memory array of CIM according to the preferred embodiment of the present disclosure;

FIG. 9 is a schematic diagram of an operation method for a memory array according to a preferred embodiment of the disclosure;

FIG. 10 is a schematic diagram of a memory array for the CIM according to another preferred embodiment of the present disclosure;

FIG. 11 is a schematic diagram of a memory array for the CIM according to another preferred embodiment of the present disclosure; and

FIG. 12 is a schematic diagram of a memory array for the CIM according to another preferred embodiment of the present disclosure.

### DETAILED DESCRIPTION OF THE PREFERRED EMBODIMENTS

Please read the following detailed description with reference to the accompanying drawings of the present disclosure. The accompanying drawings of the present disclosure are used as examples to introduce various embodiments of the present disclosure and to understand how to implement the present disclosure. The embodiments of the present disclosure provide sufficient content for those skilled in the art to implement the embodiments of the present disclosure, or implement embodiments derived from the content of the present disclosure. It should be noted that these embodiments are not mutually exclusive from each other, and some embodiments can be appropriately combined with another one or more embodiments to form new embodiments; that is, the implementation of the present disclosure is not limited to the examples disclosed below. In addition, for the sake of brevity and clarity, relevant details are not excessively disclosed in each embodiment, and even if specific details are disclosed, examples are used only to make readers understand. The present invention will now be described more specifically with reference to the following embodiments. It is to be noted that the following descriptions of the preferred embodiments of this invention are presented herein for the purposes of illustration and description only; they are not intended to be exhaustive or to be limited to the precise form disclosed.

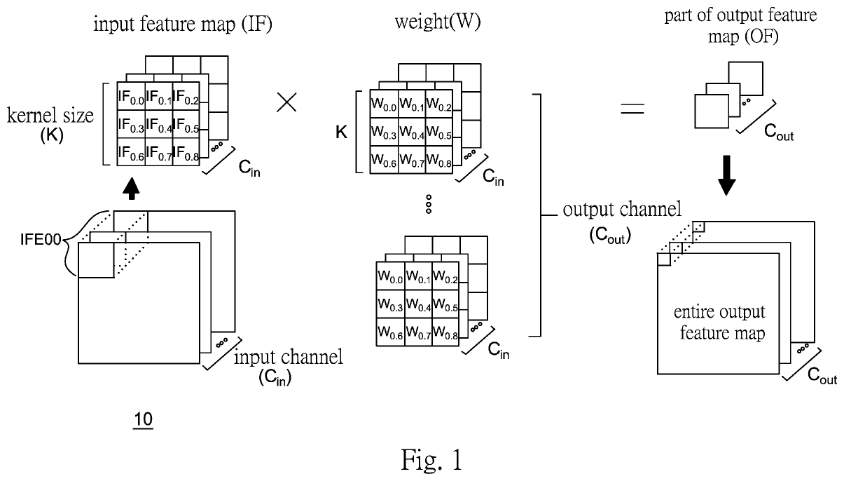

Please refer to FIG. 1, which is a schematic diagram showing multi-bit multiplication and addition 10 operated by a convolutional neural network (CNN) in a preferred embodiment of the present disclosure. The convolutional neural network operation example is shown in FIG. 1. The CNN operation method includes several point-to-point multiplication and addition. The Equation 1 for multi-bit multiplication and addition is as follows:

OUT=Σᵢ₌₀^{C}^{ᵢₙ}⁻¹Σⱼ₌₀^{K}^{²}⁻¹Partial Sum_{i,j}=Σᵢ₌₀^{C}^{ᵢₙ}⁻¹Σⱼ₌₀^{K}^{²}⁻¹IN_{i,j}[b_{A}−1:0]×W_{i,j}[b_{W}−1:0] (Eq. 1)

The Equation 1 is multi-bit multiplication and addition of neural network operations, where bA is the bit width of the input feature map, bW is the bit width of Weight, and each bit of Input and Weight has a different weight. Therefore, the equation 1 is further disassembled into: OUT=Σᵢ₌₀^{C}^{ᵢₙ}⁻¹Σⱼ₌₀^{K}^{²}⁻¹(Σ_{b}^{b}^{_{A}}2^{b}×IN_{i,j}[b])×(Σ_{b}^{b}^{_{W}}2^{b}×W_{i,j}[b]). In order to achieve high-precision neural network calculations in CIM, it is necessary to deal with the hardware architecture, so that INi,j[b] or Wi,j[b] can have weights, and thus the CIM operation can perform multi-digit multiplication.

The partial sum in Equation 1 refers to a result of the single element INi,j [bA-1:0] of the input feature map in CNN multiplied by the single element Wi,j [bW-1:0]. For example, when i=0 and j=0, a single element of the input feature map can be extended to 1^{st} width of multiple bits, such as [bA-1:0], and a single element of the weight can also be extended to 2^{nd} width of multiple bits, such as [bW-1:0]. That is to say, the partial sum represents the multiplication result of the input and the weight of the single element. K in Equation 1 represents the kernel size, Cin represents the input channel, Cout represents the output channel, and OF represents the output feature map of the part. OF includes a single element with multi-bit input multiplied by multi-bit weight, i.e., OF has multi-output of channel Cout. The multi-input channel Cin can be regarded as the result of expanding into multiple bits. For example, when the bit is binary and expanded to 4 bits, then Cin=2\hat{ }4=16; when the bit is ternary, and the bit is expanded to 4 bits, then Cin=3\hat{ }4=81, 2\hat{ }b in the disassembled Equation 1 is 3\hat{ }b, and so on. The partial sum in Equation 1 is summed from j=0 to (K\hat{ }2)-1, and summed from i=0 to Cin-1, which is equal to the multiplication and addition result of the input and weight of multiple bit cells. The result of this multiplication and addition is only the result of part output features.

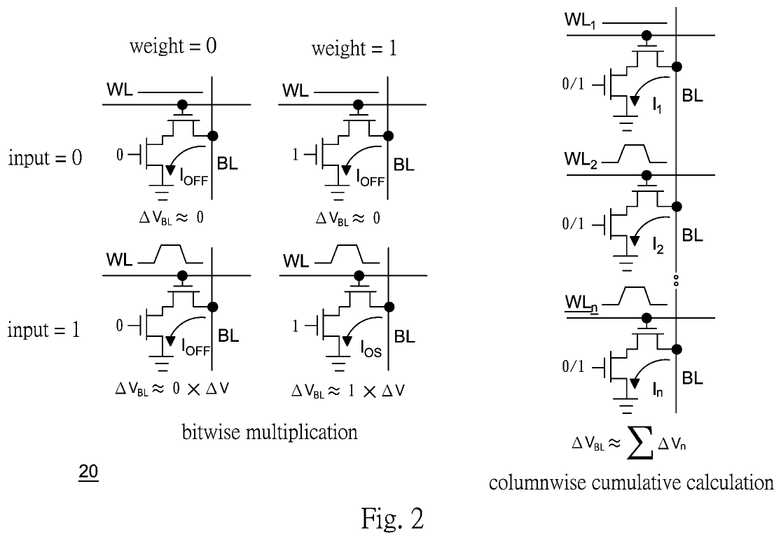

Please refer to FIG. 2, which is a schematic diagram of a CIM 20 according to a preferred embodiment of the present disclosure. Please refer to FIG. 2 and Equation 1. Taking SRAM based CIM as an example, the implementation of multiplication and addition in CIM is shown in FIG. 2. The value stored in the SRAM cell and the voltage level change of read word line (RWL) form a current or voltage difference on the read bit line (RBL), and this current or voltage difference can be regarded as the result of one-bit multiplication in CNN. There will be several SRAM cells on the RBL, and when the RWL is turned on at the same time, the results of several one-bit multiplications will be accumulated on the RBL in the form of current or voltage differences. Finally, the current or voltage difference generated on the RBL can be regarded as the accumulation result. According to the equation of multiplication and addition, the voltage level of RWL corresponds to the input IN in Equation 1, the value stored in the SRAM cell corresponds to the weight W in Equation 1, and the current or voltage difference generated by one SRAM cell or a plurality of SRAM cells corresponds to Partial Sum in the equation, the current or voltage difference generated on an entire RBL corresponds to OUT in Equation 1.

In order to implement multi-bit multiplication and addition in CIM, the present invention proposes to modify the architecture to implement the weights of different input bits of the expanded input IN, or the weights of different weight bits of the expanded weight W, so that the current or voltage difference generated by one SRAM cell or multiple SRAM cells directly generates a Partial Sum. Its principle is as follows:

$$Partial {Sum}_{i , j} = ( {\sum }_{b A = 0}^{{B}_{A} - 1} {2}^{{b}_{A}} \times {IN}_{i , j} [ b ] ) \times ( {\sum }_{b W = 0}^{{B}_{W} - 1} {2}^{b W} \times {W}_{i , j} [ b ] ) \qquad ( Eq . 2 )$$

$$\begin{matrix}{I}_{D , Lin} ∝ \frac{W}{L} [ 2 ( {V}_{G S} - {V}_{T} ) {V}_{D S} - {V}_{D S}^{2} ] & {I}_{D , Sat} ∝ \frac{W}{L} {( {V}_{G S} - {V}_{T} )}^{2}\end{matrix} \qquad ( Eq . 3 )$$

$$Δ {V}_{RBL} ≅ {\sum }_{n}^{N} {ΔV}_{Cell , n} ∝ \frac{{Q}_{RBL}}{{C}_{RBL}} = \frac{{I}_{RBL} / {t}_{RBL}}{{C}_{RBL}} = ( {\sum }_{n}^{N} {I}_{Cell , n} ) \times \frac{{t}_{RBL}}{{C}_{RBL}} \qquad ( Eq . 4 )$$

Equation 2 is the Partial Sum formula of multi-bit multiplication and addition, Equation 3 is the MOSFET current formula, and Equation 4 is the voltage and current formula of RBL.

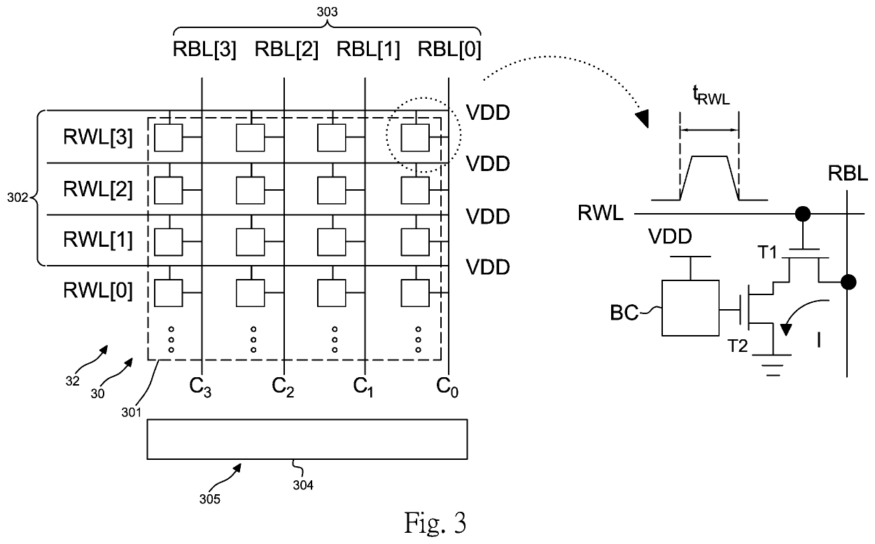

Please refer to FIG. 3, which is a schematic diagram of a memory array 30 for CIM in a preferred embodiment of the present disclosure, e.g. an SRAM-based CIM architecture 32. The memory array 30 includes a bit cell array 301, at least one word line 302, at least one bit line 303, and a readout circuit 304. The reading circuit 304 can be, for example, a conversion circuit (ADC) 305 for converting an analog signal into a digital signal. Each bit cell BC in FIG. 3 is a memory cell and is electrically connected to transistor T2. Transistor T1 is electrically connected to word line RWL and bit line RBL. When reading, word line RWL is applied to a pulse wave having a period of tRWL, the pulse wave is used as the input 1 of the CNN, and the value 1 of the stored bit of the bit cell BC is read as the weight 1 of the CNN, and the voltage difference or current on the bit line RBL is expressed as a product of an input bit and a weight bit.

Please refer to FIG. 3 and Equations 2˜4 together. The calculation of CIM can change the following parameters to make IN or W have weight, and change the size of ΔV_RBL:
(1) the quantity of the bit cell;
(2) the operating voltage VDD of the bit cell;
(3) the voltage of the Read Word line (RWL) pulse;
(4) the duration of the RWL pulse;
(5) the times of RWL pulses;
(6) the voltage of the pre-charge of the Read Bit line (RBL);
(7) the capacitance value of the capacitor on the RBL;
(8) the threshold voltage VT of the bit cell; and
(9) the transistor width in the bit cell.
   Any combination of the above (1)˜(9) parameters can change ΔV_RBL, and this disclosure uses the parameter combinations of (1), (2), and (7) as examples for illustration. It should be noted that other parameters (3)-(6) and (8)-(9) can also be combined with the parameters (1), (2) and (7) to achieve different embodiments.

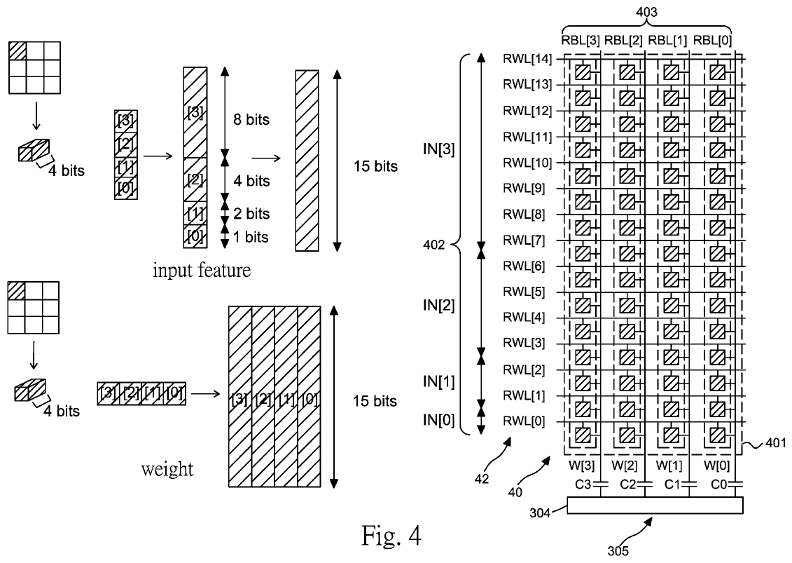

Please refer to FIG. 4, which is a schematic diagram of implementing multi-bit multiplication and addition of a memory array 40 used in a CIM according to a preferred embodiment of the present disclosure. The memory array 40 used for CIM is, for example, an SRAM-based CIM architecture 42. Please refer to FIGS. 1 and 4. Adjusting the quantity of the SRAM cell can enable the circuit to represent the inputs of multi-bits IN, which mainly includes expanding the feature map, expanding the weight, and starting the RWL for operations. The input bit expansion of the coordinate (0,0) of the input feature element IFE00 in the input feature map IF can be represented by the quantity of RWL. IN[b] uses the corresponding quantity of RWLs according to the weight represented by each bit. Taking 4 bits IN as an example, IN[3] uses 8 RWLs, IN[2] uses 4 RWLs, and IN[1] uses 2 RWLs, IN[0] use 1 RWL.

The weight of W[b] can be realized using the capacitance values 8C0, 4C0, 2C0 and 1C0 of the capacitors on the RBL and the reading circuit 304, but for the RWL position corresponding to IN[3:0], a corresponding quantity of SRAM cells must be used. Taking 4 bits IN as an example, each W[b] must be represented by 4²−1=15 SRAM cells.

In another embodiment, the weight of W[b] can be realized by using the quantity of bit cells BC in the word line RWL direction, or can be achieved by providing different operating voltages VDD with different RBL bit cells BC by a voltage regulation circuit, both of which can save the capacitor on the read circuit 304.

Turning on RWL to carry out calculation means multiplying IN and W to execute multiplication and addition in CIM. Each RBL can get W[b]×(8×IN[3]+4×IN[2]+2×IN[1]+1×IN[0]), and finally the read circuit 304 (such as the conversion circuit 305 for converting analog signals to digital signals) performs charge sharing to obtain IN[3:0]×W[3:0] multiplication and addition result.

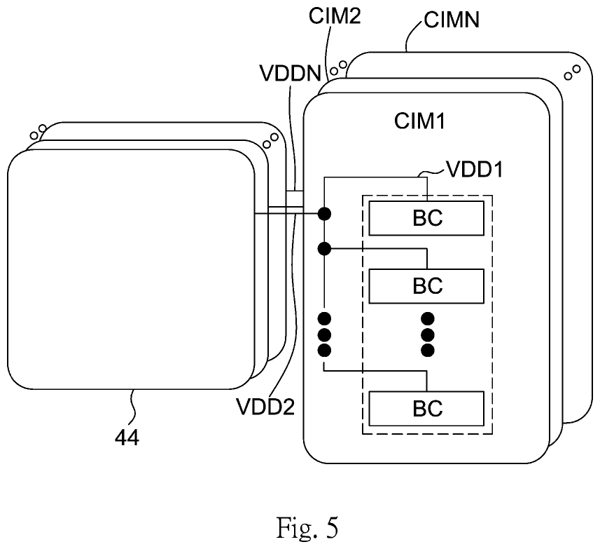

In another way and structure of extending the input bits, adjusting the operating voltage VDD of the bit cell BC in the SRAM cell structure 42 can also make the circuit represent the multiple bits IN. Please refer to FIG. 5, which is a schematic diagram of using the voltage regulating circuit 44 to provide different operating voltages VDD1, VDD2, . . . , VDDN to multiple bit cells CIM1, CIM2, . . . , CIMN according to a preferred embodiment of the present disclosure. The voltage regulation circuit 44 can not only adjust the operation voltages VDD1, VDD2, . . . , VDDN of the operation units CIM1, CIM2, . . . , CIMN in CIM, but also can overcome the effects of process and operating temperature variations in the large scale calculation units.

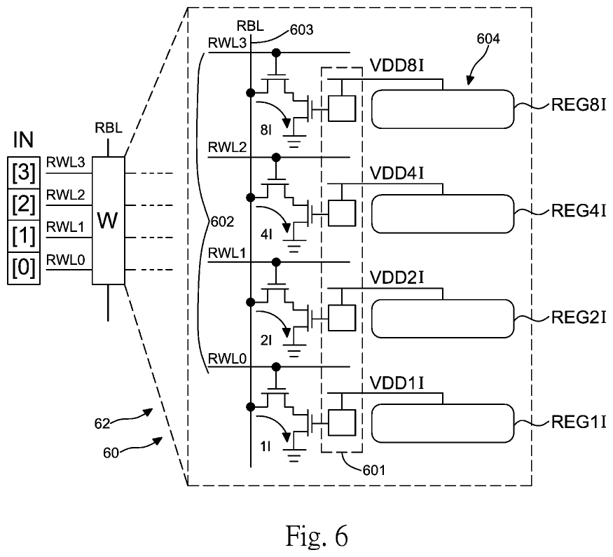

Please refer to FIG. 6, which is a schematic diagram of providing different operating voltages to bit cells to implement multiplication and addition of multi-input bits for a memory array 60 used in CIM according to a preferred embodiment of the present disclosure. The memory array 60 is, for example, an SRAM-based CIM structure 62, which includes a column of bit cells 601, a plurality of word lines 602, a bit line 603, and a voltage regulation circuit 604 that can provide different operation voltages VDD8I, VDD4I, VDD2I, VDD1I for the column of bit cells 601. The voltage regulation circuit 604 includes sub-regulation circuits REG8I, REG4I, REG2I and REG1I. In the embodiment of FIG. 4, the quantity of bit cells is used to expand one input bit into 4 input bits IN[3:0], which can be changed to provide different operating voltages VDD8I VDD4I, VDD2I, VDD1I for the column of bit cells 601 in the embodiment of FIG. 6, so as to realize the expansion of the input bit. The fourth bit IN[3] in FIG. 4 can be alternatively represented by only one word line RWL3 and a bit cell BC in FIG. 6, but 8 units of electrical parameters is provided to the bit cell BC to represent the weight magnitude of the fourth bit IN[4]. The electrical parameter includes at least one of a current, a charge, and a voltage. The third bit IN[2] in FIG. 4 can be alternatively represented by only one word line RWL2 and a bit cell BC in FIG. 6, but 4 units of electrical parameters is provided to the bit cell BC to represent the weight magnitude of the third bit IN[2]. The second bit IN[1] in FIG. 4 can be alternatively represented by only one word line RWL1 and a bit cell BC in FIG. 6, but 2 units of electrical parameters is provided to the bit cell BC to represent the weight magnitude of the second bit IN[1]. The first bit IN[0] in FIG. 4 can be alternatively represented by only one word line RWL0 and a bit cell BC in FIG. 6, but 1 unit of electrical parameter is provided to the bit cell BC to represent the weight magnitude of the first bit IN[0].

The embodiment of FIG. 6 only expands the input bit of CNN so that each bit has a different weight magnitude, and the weight bit of CNN has not yet been expanded, so Equation 2 can be simplified as:

Partial Sum=Σ_{b}_{_{A}}₌₀^{B}^{_{A}}⁻¹2^{b}^{_{A}}×IN_{i,j}[b_{A}]×W_{i,j}[b_{W}] (Eq. 5)

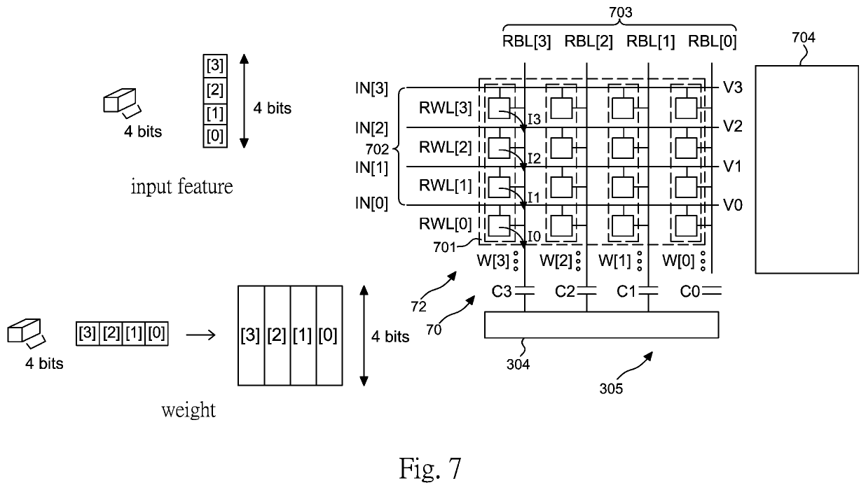

Please refer to FIG. 7, which is a schematic diagram of providing different operating voltages to bit cells to implement multiplication and addition of multi-input bits for a memory array 70 used in CIM according to another preferred embodiment of the present disclosure. The memory array 70 is, for example, an SRAM-based CIM structure 72, which includes a bit cell array 701, a plurality of word line 702, a plurality of bit line 703, and a voltage regulation circuit 704 that can provide the bit cell array 701 with different operating voltages V3, V2, V1, V0. The implementing steps include: writing weights, lowering SRAM operating voltages, and starting RWL for operations.

When writing the weight W of CNN, the corresponding 4 bits IN of the weight data is expanded into 4 bits in the RBL direction, as shown in FIG. 7. The voltage is maintained at the normal operating voltage, so that the weight data can be written smoothly.

After the weight W of CNN is written, the voltage regulation circuit 704 provides four different operating voltages V3, V2, V1, V0 to the SRAM cells on the four RWL[3], RWL[2], RWL[1] and RWL[0], so that the SRAM cell has four output currents I3, I2, I1 and I0 having different weights, which are respectively represented as weights of input bits IN[3], IN[2], IN[1], IN[0], wherein the greater the voltage or current, the greater the weight is, and vice versa.

Then, in this corresponding way of IN and W, RWL is turned on to perform multiplication and addition in CIM, and each RBL can obtain W[b]×(I3×IN[3]+I2×IN[2]+I1×IN[1]+I0×IN[0]), wherein the current I3=2×I2=4×I1=8×I0 generated by the SRAM cell is caused by the voltage regulation circuit 704, and finally the conversion circuit (e.g. ADC convertor) 305 perform charge sharing to obtain the multiplication and addition result of IN[3:0]×W[3:0]. The weight of W[b] can be realized by using RBL and capacitors C3, C2, C1 and C0 having capacitance values 8C0, 4C0, 2C0 and 1C0 respectively on the reading circuit 304.

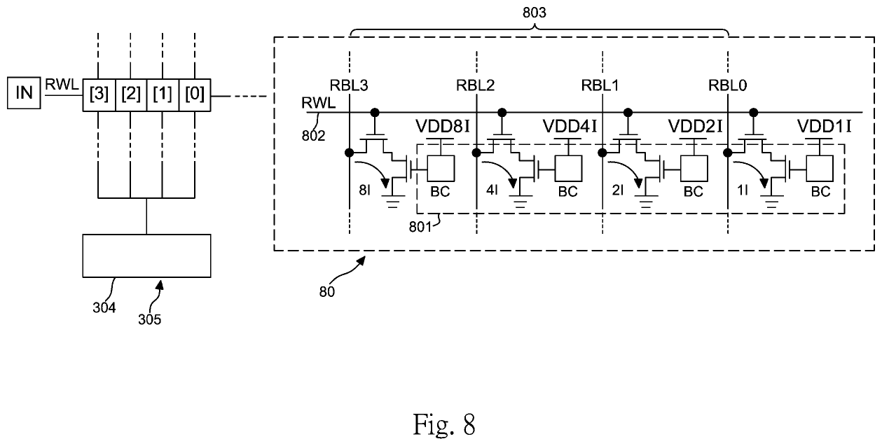

Please refer to FIG. 8, which is a schematic diagram of providing different operating voltages VDD8I, VDD4I, VDD2I and VDD1I to the bit cells BC to implement multi-weight bit multiplication and addition for the memory array 80 of CIM according to the preferred embodiment of the present disclosure. The input bit IN in FIG. 8 has only 1 bit, which is represented by a word line. In any embodiment of the present disclosure, the voltage applied to the word line during reading is all static, which is not based on the number of pulses or the pulse width to represent the weight of the CNN input, so that the power consumption can be greatly saved, and the complexity of the circuit supplying power to the word line can be reduced. It can be seen in FIG. 8 that the weight bits W[3], W[2], W[1] and W[0] are respectively represented by different operating voltages VDD8I, VDD4I, VDD2I and VDD1I applied to the bit cells BC.

The embodiment of FIG. 8 only expands the input bit of CNN, so that each bit has a different weight magnitude, and the weight bit of CNN has not yet been expanded, so Equation 1 can be simplified as:

Partial Sum=Σ_{b}_{_{W}}₌₀^{B}^{_{W}}⁻¹2^{b}^{_{W}}×IN_{i,j}[b_{A}]×W_{i,j}[b_{W}] (Eq. 6)

From the descriptions of the above-mentioned multiple embodiments, the memory arrays 30, 40, 60, 70, and 80 used for in-memory operations (CIM) in the present disclosure can be summarized as follows. A memory array 30, 40, 60, 70, 80 used for computing-in-memory (CIM) includes a bit cell array 301, 401, 601, 701, 801, at least one word line 302, 402, 602, 702, 802, at least one bit line 303, 403, 603, 703, 803, and a reading circuit 304. The bit cell array 301, 401, 601, 701, 801 includes a plurality of bit cells, wherein each of the plurality of bit cells has a storage bit and operates at an operating voltage VDD1, VDD2, . . . , VDDN, and the plurality of storage bits are associated with a weight bit W of a convolutional neural network (CNN). The at least one word line 302, 402, 602, 702 is electrically connected to the bit cell array 301, 401, 601, 701, 801, wherein the at least one of word line 302, 402, 602, 702, 802 is associated with an input bit of the CNN. The at least one bit line 303, 403, 603, 703, 803 is electrically connected to the bit cell array 301, 401, 601, 701, 801, wherein the plurality of bit cells are arranged along at least one of a bit line direction and a word line direction, each the at least one bit line 303, 403, 603, 703, 803 has an electrical parameter, a first plurality of bit cells of the bit cell array 301, 401, 601, 701, 801 are arranged along the bit line RBL direction according to a first arrangement quantity bA, the memory array 30, 40, 60, 70, 80 expands the input bit IN[0] of the CNN to a plurality of input bits IN[bA-1], IN[bA-2], . . . , IN[1], IN[0] based on at least one of the first arrangement quantity bA and the operating voltage VDD1, VDD2, . . . , VDDN, and at least one of the first arrangement quantity bA and the operating voltage VDD1, VDD2, . . . , VDDN is a first weight 2^{bA-1}, 2^{bA-2}, . . . , 2¹, 2⁰ associated with the first plurality of input bits IN[bA-1], IN[bA-2], . . . , IN[1], IN[0]. The reading circuit 304 is electrically connected to the plurality of bit lines RBL, and senses the electrical parameter of each of the plurality of bit lines RBL to obtain a multiplication and addition result Partial Sum of the plurality of input bits IN[bA-1], IN[bA-2], . . . , IN[1], IN[0] of the CNN and the corresponding weight bits W thereof.

In any embodiment of the present disclosure, the electrical parameter includes at least one of a current, a charge, and a voltage. The memory arrays 30, 40, 60, 70, 80 further include at least one voltage regulation circuit 44 to provide the operating voltages VDD1, VDD2, . . . , VDDN. The magnitude of the operating voltage VDD is positively related to the first weight 2^{bA-1}, 2^{bA-2}, . . . , 2¹, 2⁰ of the plurality of input bits IN[bA-1], IN[bA-2], . . . , IN[1], IN[0]. The first arrangement number bA is positively related to the first weights 2^{bA-1}, 2^{bA-2}, . . . , 2¹, 2⁰. The reading circuit 305 includes complex capacitors C3, C2, C1 and C0, and the plurality of capacitors C3, C2, C1 and C0 are respectively one-to-one corresponding to the plurality of bit lines RBL[3], RBL[2], RBL[1], RBL[0] to obtain the Partial Sum of the multiplication and addition result. The memory array 30, 40, 60, 70, 80 further includes an analog-to-digital conversion circuit (ADC) 305 as the read circuit 304, and the Partial Sum of the multiplication and addition result is converted to a digital data by the ADC conversion circuit 305.

In any embodiment of the present disclosure, the plurality of bit cells BC are arranged along a word line RWL direction according to a second arrangement quantity bW. The memory array 30, 40, 60, 70, 80 expands a weight bit W[b] of the CNN to the plurality of weight bits W[bW-1], W[bW-2], . . . , W[1], W[0] according to the second arrangement quantity bW and at least one of the operating voltages VDD1, VDD2, . . . , VDDN, and at least one of the second arrangement quantity bW and the operating voltage VDD1, VDD2, . . . , VDDN is associated with a second weight 2^{bW-1}, 2^{bW-2}, . . . , 2¹, 2⁰ of the plurality of weight bits W[bW-1], W[bW-2], . . . , W[1], W[0].

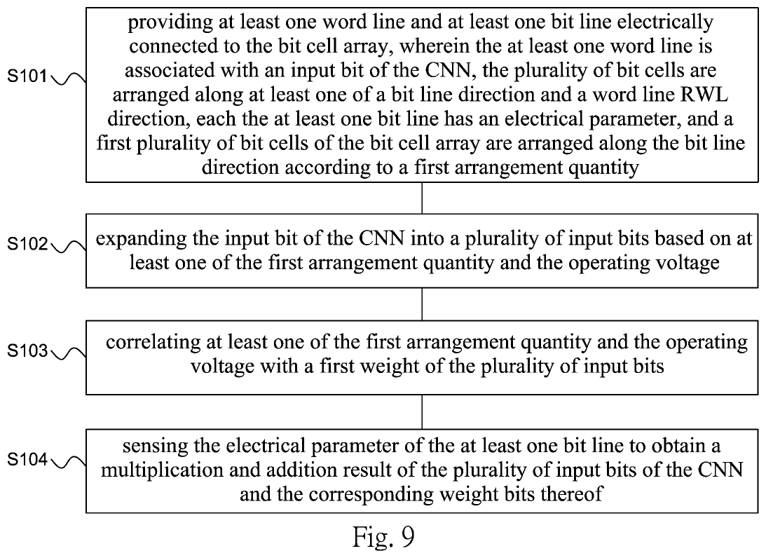

Please refer to FIG. 9, which is a schematic diagram of an operation method S10 for a memory array according to a preferred embodiment of the disclosure, wherein the memory array includes a bit cell array 301, 401, 601, 701, 801, each bit cell BC of the bit cell array 301, 401, 601, 701, 801 has a storage bit and an operating voltage VDD, the plurality of storage bits are associated with a weight bit of a convolutional neural network (CNN), and the method includes the following steps: providing at least one word line RWL and at least one bit line RBL electrically connected to the bit cell array 301, 401, 601, 701, 801, wherein the at least one word line RWL is associated with an input bit IN of the CNN, the plurality of bit cells BC are arranged along at least one of a bit line RBL direction and a word line RWL direction, each the at least one bit line RBL has an electrical parameter, and a first plurality of bit cells of the bit cell array 301, 401, 601, 701, 801 are arranged along the bit line RBL direction according to a first arrangement quantity bA (S101); expanding the input bit IN[b] of the CNN into a plurality of input bits IN[bA-1], IN[bA-2], . . . , IN[1], IN[0] based on at least one of the first arrangement quantity bA and the operating voltage VDD (S102); correlating at least one of the first arrangement quantity bA and the operating voltage VDD with a first weight 2^{bA-1}, 2^{bA-2}, . . . , 2¹, 2⁰ of the plurality of input bits IN[bA-1], IN[bA-2], . . . , IN[1], IN[0] (S103); and sensing the electrical parameter of the at least one bit line RBL to obtain a multiplication and addition result Partial Sum of the plurality of input bits IN[bA-1], IN[bA-2], . . . , IN[1], IN[0] of the CNN and the corresponding weight bits W thereof (S104).

In any embodiment of the present disclosure, wherein the plurality of bit cells BC is arranged along the word line RWL direction according to a second arrangement quantity bW, the operation method S10 further includes the following steps: expanding a weight bit W[b] of the CNN into a plurality of weight bits W[bW-1], W[bW-2], . . . , W[1], W[0] according to at least one of the second arrangement quantity bW and the operating voltages VDD1, VDD2, VDDN; and associating at least one of the second arrangement quantity bW and the operating voltages VDD1, VDD2, . . . , VDDN with a second weight 2^{bW-1}, 2^{bW-2}, . . . , 2¹, 2⁰ of the plurality of weight bits W[bW-1], W[bW-2], . . . , W[1], W[0].

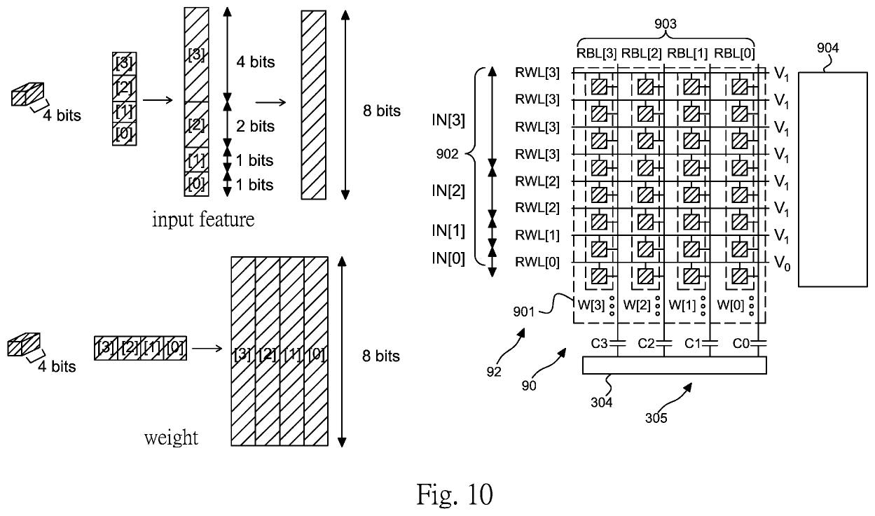

Please refer to FIG. 10, which is a schematic diagram of a memory array for the CIM according to another preferred embodiment of the present disclosure. The embodiment in FIG. 10 expands the input bit IN in a mixed manner by the quantity of bit cells bA and different operating voltages V1, V2. The memory array 90 is, for example, an SRAM-based CIM structure 92, which includes a bit cell 601 array 901, a plurality of word line 902, a plurality of bit line 903, and a voltage regulation circuit 904 that can provide the bit cell array 901 with different operating voltages V1, V0. The implementation steps include: expanding the input feature map IF, expanding the weight W, writing the weight W, lowering the SRAM operating voltage, and starting the RWL for calculation.

Regarding the expanded input feature map, in the embodiment of FIG. 10, the SRAM cell has two operating voltages V1, V0, and the SRAM cell can produce double or double weight currents. Compared to (1) that only uses the method of adjusting the quantity of IN[b], the quantity of cells corresponding to IN[b] having more than twice the weight can be reduced. Taking 4 bits IN as an example, IN[3] uses 4 RWLs, and IN[2] uses 2 RWLs, IN[1] uses 1 RWL, IN[0] uses 1 RWL, wherein IN[3:1] corresponds to a cell having twice the weight current; IN[0] corresponds to a cell having 1 times the weight current .

Regarding the expansion weight W, for the RWL position corresponding to IN[3:0], a corresponding quantity of SRAM cells must be used. Taking 4 bits IN as an example, each W[b] must use 8 SRAM cell to represent.

Regarding the write weight W, when writing the weight, expand the weight data corresponding to 4 bits IN in the RBL direction into 4 bits in the RBL direction according to the method of FIG. 10, and when writing the weight, the voltage regulator 904 keeps the SRAM the operating voltage to maintain at the normal operating voltage, so that the weight data can be written smoothly.

Regarding reducing the SRAM operating voltage, after the weight W is written, the voltage regulator 904 is used to make the SRAM cells on the four RWLs to use two different operating voltages V1, V0, so that the SRAM cells have two output currents having different weight current.

Regarding starting RWL to perform calculations, in this way of corresponding IN and W, start RWL to perform multiplication and addition for CIM, and each RBL can get W[b]×(I₁×4×IN[3]+I₁×2×IN[2]+I₁×IN[1]+I₀×IN[0]), wherein the voltage regulation circuit 904 causes the SRAM cell to generate the current I₁=2×I₀, and finally the conversion circuit (ADC) 305 performs charge sharing to obtain the multiplication and addition result of IN[3:0]×W[3:0]. The weight magnitude of W[b] can be realized by using RBL and capacitors C3, C2, C1, and C0 on the reading circuit 304 having capacitance values 8C0, 4C0, 2C0, and 1C0.

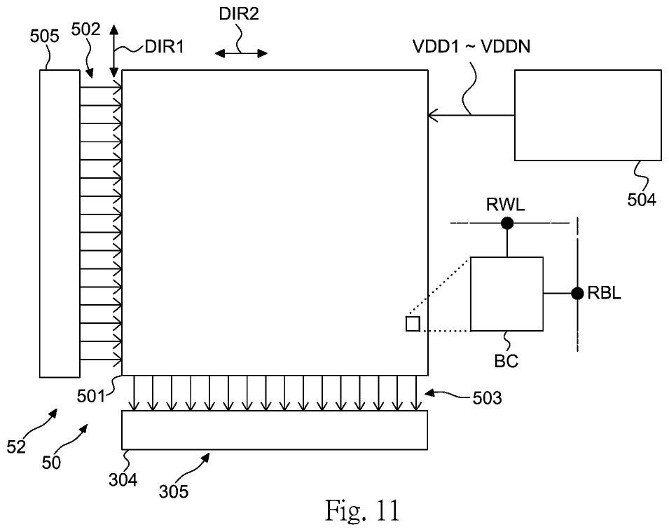

In any embodiment of the present disclosure, the disclosed memory array and its operation method for in-memory operation (CIM) can also be applied to multiplication and addition of multiple parameters, not limited to multiplication and addition of input features and weights of a single element of CNN. Please refer to FIG. 11, which is a schematic diagram of a memory array 50 for operation CIM according to another preferred embodiment of the present disclosure. A memory array 50 for operation in memory (CIM) includes a bit cell (Bit Cell) array 501, at least one word line 502, and at least one bit line 503, wherein each bit cell BC is operated by an operating voltage VDD1, VDD2, . . . , VDDN. The at least one word line 502 is electrically connected to the bit cell array 501, wherein the at least one word line RWL is associated with a first parameter IN. The at least one bit line 503 is electrically connected to the bit cell array 501, wherein the bit cell BC extends along with at least one of a first DIR1 and a second direction DIR2, wherein each the at least one bit line has an electrical parameter associated therewith, a first plurality of bit cell BC of the bit cell array 501 extends a first quantity bA along with the first direction DIR1, and the memory array 50 determines a first weight 2^{bA-1}, 2^{bA-2}, . . . , 2¹, 2⁰ of the first parameter IN based on at least one of the first quantity bA and the operating voltages VDD1, VDD2, . . . , VDDN.

Any embodiment of the present disclosure can be applied to other types of memory cells, such as ReRAM or MRAM.

In any embodiment of the present disclosure, without changing the structure of the bit cell itself, the bit cell BC is statically processed. The embodiments include Embodiment I by changing the quantity of the bit cell BC, Embodiment II by changing the operating voltage of the bit cell BC, and Embodiment III by combining Embodiment I with Embodiment II. Other methods that enable the bit cell BC to generate a weighted current to represent multi-bit input signals are within the scope of the embodiments of the present disclosure.

The implementation of the above Embodiments I, II, III is as follows:

I. This disclosure uses the quantity of the bit cell BC to represent the weight. It only needs to start the read driver 505 (such as RWL) once to complete the multiplication and addition operation, and there is no need to do analog processing on the RWL signal. In the prior art, it is necessary to start RWL multiple times, change the RWL pulse width or change the RWL signal magnitude. In comparison, the present technology can reduce hardware complexity and reduce operation delay.

II. In the present disclosure, the voltage regulator 504 is used to generate different operating voltages VDD1˜VDDN, the weight is represented by changing the operating voltage of the bit cell BC, and multiplication and addition operations are completed only by starting the read driver 505 (such as RWL) once. The present disclosure does not need to modify the structure of the bit cell BC itself, nor do analog processing of the RWL signal. In the prior art, the conventional technologies would modify the bit cell BC or perform dynamic analog processing on the word line RWL to achieve the weight represents, which will increase the complexity of the hardware and increase the power consumption of the circuit. On the contrary, the present technology can have lower hardware complexity by statically changing the operating voltage, and reduce the power consumption of the CIM by lowering the operating voltage at the same time.

III. Combining the above two methods, and the present disclosure to represents the weight by the quantity of bit cells BC and changing the operating voltage of the bit cell BC.

In any embodiment of the present disclosure, the first parameter IN is related to an input bit IN[b] of a convolutional neural network (CNN). Each bit cell BC has a storage bit, and each storage bit is related to a second parameter W, and the second parameter W is related to a weight bit W[b] of the CNN. The weight bit W[b] is associated with a single weight element Wi,j (e.g., W00 in FIG. 1) of the CNN. The input bit IN[b] is related to a single input element INi,j of the CNN (e.g., IN00 in FIG. 1). The first direction DIR1 is the direction of a bit line RBL. The memory array 50 expands the input bit IN[b] of the CNN to a plurality of input bits IN[bA-1], IN[bA-2], . . . IN[1], IN[0] according to at least one of the quantity bA and the operating voltage VDD1˜VDDN], IN[0], and the at least one of the first quantity bA and the operating voltage VDD1˜VDDN is related to a first weight magnitude 2^{bA-1}, 2^{bA-2}, . . . , 2¹, 2⁰ of the plurality of input bits IN[bA-1], IN[bA-2], . . . IN[1], IN[0].

In any embodiment of the present disclosure, each bit cell BC has a storage bit, and each storage bit is related to a second parameter W, and the second parameter W is related to a weight bit W[b] of the CNN. The second direction DIR2 is a word line RWL direction. A second plurality of bit cells of the bit cell array 50 extends a second quantity bW along with the second direction DIR2, and the memory array 50 determines a second weight magnitude 2^{bW-1}, 2^{bW-2}, . . . , 2¹, 2⁰ of the second parameter W based on at least one of the second quantity bW and the operating voltages VDD1˜VDDN.

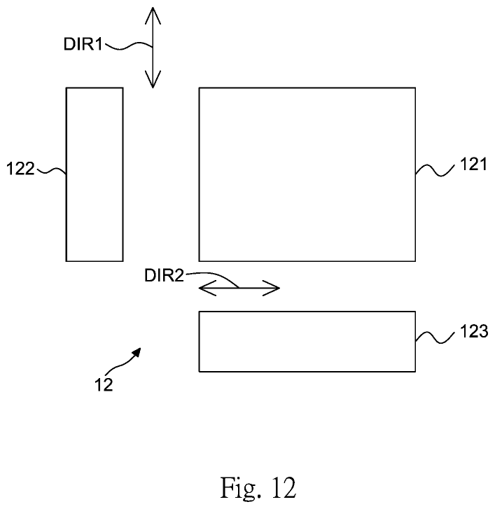

Please refer to FIG. 12, which is a schematic diagram of a memory array 12 for CIM according to another preferred embodiment of the present disclosure. The memory array 12 for CIM includes a bit cell array 121, at least one word line 122, and at least one bit line 123, wherein each bit cell BC is operated at an operating voltage VDD1, VDD2, . . . , VDDN. The at least one word line 122 is electrically connected to the bit cell array 121, wherein each word line RWL is associated with a first parameter IN. The at least one bit line 123 is electrically connected to the bit cell array 121, and the bit cell BC extends along a direction DIR1, DIR2, wherein each bit line RBL has an electrical parameter, each bit cell BC store a second parameter W, a first plurality of bit cell of the bit cell array 12 extends a first quantity bA/bW along the direction DIR1/DIR2, and the memory array 12 determines that the expanded one is at least one of the first parameter IN and the second parameter W according to the direction DIR1/DIR2.

In any embodiment of the present disclosure, the directions DIR1, DIR2 are only along the direction of the bit line RBL, only along the direction of the word line RWL, or along the direction of the word line RWL and along the direction of the bit line RBL. The first parameter IN is related to an input bit IN[b] of a convolutional neural network (CNN). Each bit cell BC has a storage bit related to a second parameter W, and the second parameter W is related to a weight bit W[b] of the CNN. The weight bit is associated with a single weight element Wi,j (e.g., W00 in FIG. 1) of the CNN. The input bit is associated with a single input element INi,j (e.g., IN00 in FIG. 1) of the CNN. A first plurality of bit cells BC of the bit cell array 121 extends a first quantity bA along the direction of the bit line RBL, and the memory array 12 determines a first weight magnitude 2^{bA-1}, 2^{bA-2}, . . . , 2¹, 2⁰ of the first parameter IN according to at least one of the first quantity bA and the operating voltages VDD1˜VDDN. The memory array 12 expands the input bits IN[b] of the CNN to a plurality of input bits IN[bA-1], IN[bA-2], . . . IN[1], IN[0] according to at least one of the first quantity bA and the operating voltage VDD1˜VDDN, and at least one of the first quantity bA and the operating voltage VDD1˜VDDN is related to the first weight magnitudes of IN[bW-1], IN[bW-2], . . . IN[1], IN[0] 2^{bA-1}, 2^{bA-2}, . . . , 2¹, 2⁰ of the plurality of input bits IN[bA-1], IN[bA-2], . . . IN[1], IN[0]. A second plurality of bit cells BC of the bit cell array 121 extends a second quantity bW along the direction of the word source line RWL, and the memory array 12 determines a second weight magnitudes 2^{bW-1}, 2^{bW-2}, . . . , 2¹, 2⁰ of the second parameter W based on at least one of the second quantity bW and the operating voltages VDD1˜VDDN.

While the invention has been described in terms of what is presently considered to be the most practical and preferred embodiments, it is to be understood that the invention need not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A memory array used for computing-in-memory (CIM), comprising:
a bit cell array including a plurality of bit cells, wherein each of the plurality of bit cells has a storage bit and operates at an operating voltage, and the plurality of storage bits are associated with a weight bit of a convolutional neural network (CNN);
at least one word line electrically connected to the bit cell array, wherein the at least one of word line is associated with an input bit of the CNN;
at least one bit line electrically connected to the bit cell array, wherein the plurality of bit cells are arranged along at least one of a bit line direction and a word line direction, each the at least one bit line has an electrical parameter, a first plurality of bit cells of the bit cell array are arranged along the bit line direction according to a first arrangement quantity, the memory array expands the input bit of the CNN to a plurality of input bits based on at least one of the first arrangement quantity and the operating voltage, and at least one of the first arrangement quantity and the operating voltage is a first weight associated with the first plurality of input bits; and
a reading circuit electrically connected to and sensing the electrical parameter of each the at least one bit line to obtain a multiplication and addition result of the plurality of input bits of the CNN and the corresponding weight bits thereof.

2. The memory array for CIM as claimed in claim 1, wherein the electrical parameter includes at least one of a current, a charge, and a voltage.

3. The memory array for CIM as claimed in claim 1, wherein:
the memory array further includes at least one voltage regulation circuit to provide the operating voltage; and
the operating voltage has a magnitude which is positively correlated with the first weight of the plurality of input bits.

4. The memory array for CIM as claimed in claim 1, wherein the first arrangement quantity is positively correlated with the first weight of the plurality of input bits.

5. The memory array for CIM as claimed in claim 1, wherein the reading circuit includes at least one capacitor corresponding to the at least one bit line to obtain the multiplication and addition result.

6. The memory array for CIM as claimed in claim 1, wherein the memory array further includes an analog-to-digital conversion circuit serving as the reading circuit for converting the multiplication and addition result into a digital data.

7. The memory array for CIM as claimed in claim 1, wherein:
the plurality of bit cells are arranged along the word line direction according to a second arrangement quantity; and
the memory array expands the weight bit of the CNN into a plurality of weight bits based on the second arrangement quantity and the operation voltage, and the second arrangement quantity and the operation voltage is associated with a second weight of the plurality of weight bits.

8. A method for operating a memory array, wherein the memory array includes a bit cell array including a plurality of bit cells, each of which has a storage bit and an operating voltage, the plurality of storage bits are associated with a weight bit of a convolutional neural network (CNN), and the method includes the following steps:
providing at least one word line and at least one bit line electrically connected to the bit cell array, wherein the at least one word line is associated with an input bit of the CNN, the plurality of bit cells are arranged along at least one of a bit line direction and a word line direction, each the at least one bit line has an electrical parameter, and a first plurality of bit cells of the bit cell array are arranged along the bit line direction according to a first arrangement quantity;
expanding the input bit of the CNN into a plurality of input bits based on at least one of the first arrangement quantity and the operating voltage;
correlating at least one of the first arrangement quantity and the operating voltage with a first weight of the plurality of input bits; and
sensing the electrical parameter of the at least one bit line to obtain a multiplication and addition result of the plurality of input bits of the CNN and the corresponding weight bits thereof.

9. The method for operating a memory array as claimed in claim 8, wherein:
the plurality of bit cells are arranged along the word line direction according to a second arrangement quantity; and
the method further includes steps of:
expanding the weight bit of the CNN into a plurality of weight bits based on the second arrangement quantity and the operating voltage; and
correlating the second arrangement quantity and the operating voltage with a second weight of the plurality of weight bits.

10. The method for operating a memory array as claimed in claim 8, wherein the weight bit is associated with a single weight element of the CNN.

11. The method for operating a memory array as claimed in claim 8, wherein the input bit is associated with a single input element of the CNN.

12. The method for operating a memory array as claimed in claim 8, wherein the memory array further includes a reading circuit electrically connected to the at least one bit line, and sensing an electrical parameter of the at least one bit line to obtain a multiplication and addition result of the plurality of input bits of the CNN and the corresponding weight bits thereof.

13. The method for operating a memory array as claimed in claim 8, wherein the electrical parameter includes at least one of a current, a charge, and a voltage.

14. The method for operating a memory array as claimed in claim 8, wherein:
the memory array further includes at least one voltage regulation circuit to provide the operating voltage; and
the operating voltage has a magnitude which is positively correlated with the first weight of the plurality of input bits.

15. The method for operating a memory array as claimed in claim 8, wherein the first arrangement quantity is positively correlated with the first weight of the plurality of input bits.

16. A memory array for computing-in-memory (CIM), comprising:
a bit cell array having a plurality of bit cells, wherein each bit cell is operated at an operating voltage;
at least one word line electrically connected to the bit cell array, wherein the at least one word line is associated with a first parameter; and
at least one bit line electrically connected to the bit cell array, wherein the bit cells extend along a specific direction, each the at least one bit line has an electrical parameter associated therewith, each the bit cell is associated with a second parameter, a first quantity of the plurality of bit cells of the bit cell array extends along the specific direction, and the memory array determines how an expansion associated with at least one of the first parameter and the second parameter is according to the specific direction.

17. The memory array for CIM as claimed in claim 16, wherein the direction is purely along a bit line direction, purely along a word line direction, or along both the word line direction and the bit line direction.

18. The memory array for CIM as claimed in claim 16, wherein:
the first parameter is associated with an input bit of a convolutional neural network (CNN);
each of the bit cells has a storage bit associated with the second parameter, and the second parameter is associated with a weight bit of the CNN;
the weight bit is associated with a single weight element of the CNN; and
the input bit is associated with a single input element of the CNN.

19. The memory array for CIM as claimed in claim 16, wherein:
the first parameter is associated with an input bit of a convolutional neural network (CNN);
the first quantity of the plurality of bit cells extends along a bit line direction; and
the memory array expands the input bit of the CNN to a plurality of input bits according to at least one of the first quantity and the operating voltage, and at least one of the first quantity and the operating voltage is related to a first weight magnitude of the plurality of input bits.

20. The memory array for CIM as claimed in claim 16, wherein:
the second parameter is associated with a weight bit of a convolutional neural network (CNN);
the bit cell array further includes a second quantity of bit cells extending along a word line direction; and
the memory array expands the weight bit of the CNN to a plurality of weight bits according to at least one of the second quantity and the operating voltage, and
at least one of the second quantity and the operating voltage is related to a second weight magnitude of the plurality of weight bits.
